(19) United States
(12) Patent Application Publication
(10) Pub. No.: US 2025/0287660 A1
(43) Pub. Date: Sep. 11, 2025

(54) BACKSIDE MERGED SOURCE/DRAIN CONTACT

(71) Applicant: International Business Machines Corporation, Armonk, NY (US)

(72) Inventors: Tsung-Sheng Kang, Ballston Lake, NY (US); Tao Li, Slingerlands, NY (US); Ruilong Xie, Niskayuna, NY (US); Min Gyu Sung, Latham, NY (US)

(21) Appl. No.: 18/595,566

(22) Filed: Mar. 5, 2024

(51) Int. Cl. H01L 29/08; H01L 21/8234; H01L 23/528; H01L 27/088; H01L 29/66; H01L 29/78

(52) U.S. Cl. CPC H10D 62/151; H01L 23/5286; H10D 30/024; H10D 30/62; H10D 64/017; H10D 84/013; H10D 84/0149; H10D 84/0158; H10D 84/038; H10D 84/834

(57) ABSTRACT

Embodiments of the present disclosure are directed to processing methods and resulting structures for backside merged source/drain (S/D) contacts. In a non-limiting embodiment, a first pair of merged S/D regions is formed and a second pair of merged S/D regions is formed. The first and second pairs of merged S/D regions include respective lower and upper portions. A bottom spacer is positioned under the respective upper portions of the first pair of merged S/D regions and the second pair of merged S/D regions. The bottom spacer is between the respective lower portions of the first pair of merged S/D regions and the second pair of merged S/D regions. The first pair of merged S/D regions are electrically coupled to a frontside interconnect through a merged middle of line (MOL) contact and the second pair of merged S/D regions are electrically coupled to a backside interconnect through a merged backside contact.

### BACKGROUND

The present disclosure generally relates to fabrication methods and resulting structures for semiconductor devices, and more specifically, to processing methods and resulting structures for a backside merged source/drain (S/D) contact.

The development of an integrated circuit (i.e., chip) involves several stages from design through fabrication. Many aspects of the development are performed iteratively to ensure that the chip ultimately manufactured meets all design requirements. Defining the chip architecture is one of the earliest phases of integrated circuit development. The power (e.g., power requirement), performance (e.g., timing), and area (i.e., space needed) for the resulting chip, collectively PPA (or “power, performance, area”), is one of the primary metrics by which integrated circuits are evaluated. PPA is largely a consequence of the chip architecture.

Semiconductor fabrication continues to evolve towards improving one or more aspects of PPA. For example, a higher number of active devices (mainly transistors) of ever decreasing device dimensions are placed on a given surface of semiconductor material. Density scaling has put a strain on the design and fabrication of the interconnects between the front end of line of the integrated circuit, consisting mainly of the active devices, and the contact terminals of the integrated circuit. In many chip architectures, all of these interconnects are incorporated in the back end of line (BEOL) structure of the integrated circuit, which includes a stack of metallization layers and vertical via connections built on top of the front end of line (FEOL) structure.

A key component of the BEOL structure is the power delivery network (PDN). The PDN of an integrated circuit is defined by the conductors and vias connected to the power supply (VDD) and ground (VSS) terminals of the chip. The PDN is responsible for delivering power to the individual devices in the front end. The integration of the PDN in the BEOL has become particularly challenging as device densities continue to scale. Backside power delivery is one known solution to this problem, and involves moving some (or most, or all) layers of the PDN from the front side of the integrated circuit to the back side. In a backside-style architecture, the repositioned layers are not formed on top of the FEOL, but are instead formed on the opposite side of the chip (i.e., on the backside of the semiconductor substrate onto which the active devices have been built).

### SUMMARY

Embodiments of the disclosure are directed to a method for providing backside merged source/drain (S/D) contacts. A non-limiting example of the method includes forming a first pair of merged S/D regions and a second pair of merged S/D regions. The first and second pairs of merged S/D regions include respective lower and upper portions. A bottom spacer is positioned under the respective upper portions of the first pair of merged S/D regions and the second pair of merged S/D regions. The bottom spacer is between the respective lower portions of the first pair of merged S/D regions and the second pair of merged S/D regions. The first pair of merged S/D regions are electrically coupled to a frontside interconnect through a merged middle of line (MOL) contact and the second pair of merged S/D regions are electrically coupled to a backside interconnect through a merged backside contact.

Embodiments of the disclosure are directed to a semiconductor structure. A non-limiting example of the semiconductor structure includes a first pair of merged S/D regions and a second pair of merged S/D regions. The first and second pairs of merged S/D regions include respective lower and upper portions. A bottom spacer is positioned under the respective upper portions of the first pair of merged S/D regions and the second pair of merged S/D regions. The bottom spacer is between the respective lower portions of the first pair of merged S/D regions and the second pair of merged S/D regions. The first pair of merged S/D regions are electrically coupled to a frontside interconnect through a merged middle of line (MOL) contact and the second pair of merged S/D regions are electrically coupled to a backside interconnect through a merged backside contact.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1A is a top-down reference view of a semiconductor wafer after an initial set of processing operations according to one or more embodiments;

FIG. 1B depicts a cross-sectional view taken along the line Y (across channel in source/drain region) in FIG. 1A according to one or more embodiments;

FIGS. 2A and 2B depict cross-sectional views of the semiconductor wafer of FIG. 1A taken along the lines Y and X (across gate in channel region), respectively, after a processing operation according to one or more embodiments;

FIGS. 3A and 3B depict cross-sectional views of the semiconductor wafer of FIG. 1A taken along the lines Y and X, respectively, after a processing operation according to one or more embodiments;

FIGS. 4A and 4B depict cross-sectional views of the semiconductor wafer of FIG. 1A taken along the lines Y and X, respectively, after a processing operation according to one or more embodiments;

FIGS. 5A and 5B depict cross-sectional views of the semiconductor wafer of FIG. 1A taken along the lines Y and X, respectively, after a processing operation according to one or more embodiments;

FIGS. 6A and 6B depict cross-sectional views of the semiconductor wafer of FIG. 1A taken along the lines Y and X, respectively, after a processing operation according to one or more embodiments;

FIGS. 7A and 7B depict cross-sectional views of the semiconductor wafer of FIG. 1A taken along the lines Y and X, respectively, after a processing operation according to one or more embodiments;

FIGS. 8A and 8B depict cross-sectional views of the semiconductor wafer of FIG. 1A taken along the lines Y and X, respectively, after a processing operation according to one or more embodiments;

FIGS. 9A and 9B depict cross-sectional views of the semiconductor wafer of FIG. 1A taken along the lines Y and X, respectively, after a processing operation according to one or more embodiments;

FIGS. 10A and 10B depict cross-sectional views of the semiconductor wafer of FIG. 1A taken along the lines Y and X, respectively, after a processing operation according to one or more embodiments; and

FIG. 11 depicts a flow diagram illustrating a method according to one or more embodiments.

The diagrams depicted herein are illustrative. There can be many variations to the diagram or the operations described therein without departing from the spirit of the disclosure. For instance, the actions can be performed in a differing order or actions can be added, deleted or modified.

In the accompanying figures and following detailed description of the described embodiments of the disclosure, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the disclosure are described in connection with a particular transistor architecture, embodiments of the disclosure are not limited to the particular transistor architectures or materials described in this specification. Rather, embodiments of the present disclosure are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present disclosure, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

As discussed previously, a key component of the BEOL structure is the power delivery network (PDN). Backside power delivery, also referred to as a backside power delivery network (BSPDN), is a chip architecture that involves repositioning layers of the PDN from the top of the FEOL to the opposite side of the chip to free space on the front side for additional elements (e.g., more transistors). In other words, in a backside-style architecture the PDN layers are placed on the backside of the semiconductor substrate onto which the active devices have been built.

Some challenges remain, however, in effectively placing the various backside power rails and backside contacts (e.g., gate, source, and/or drain contacts) required to provide electrical continuity to the backside devices of these architectures. For example, the placement of a backside source/drain contact relies upon a so-called backside placeholder (also referred to as the backside contact placeholder) that is built into the structure during the FEOL. The backside placeholder can then be opened post wafer flip to allow backside access to the source/drain and/or gate. The backside placeholder is built between the surrounding shallow trench isolation (STI), and access to the backside placeholder, and subsequent backside contact, is limited to a relatively deep placeholder cavity etch (e.g., a placeholder cavity RIE) that punches through the STI, typically inserted post-nanosheet recess and after the inner spacer formation. As a result, cross-sectional access to the backside contact is limited to the width of the placeholder cavity etch and a somewhat high backside contact resistance can be expected.

This disclosure introduces new fabrication methods and resulting structures for providing a backside merged source/drain (S/D) contact. Rather than relying on a deep placeholder cavity etch to cut through the STI for backside contact access, the STI module is omitted entirely, replaced instead with a backside interlayer dielectric (BILD). The BILD can be opened (patterned) as needed to provide relatively wide access to the backside contact and, consequently, a relatively lower contact resistance. In some embodiments, the STI is replaced with a relatively thin bottom spacer that can be patterned from the frontside during the FEOL. In some embodiments, two or more backside contact regions can be merged to provide even lower contact resistances, taking advantage of the fact that the BILD can be patterned more easily than STI. In some embodiments, a backside trench epitaxy can be formed over exposed source/drain regions to further lower contact resistances. Notably, the present disclosure leverages the fact that the STI was conventionally needed due to the presence of a silicon substrate, as the STI helps to prevent inter-device leakage. However, if the silicon substrate is replaced with a BILD, the wafer no longer needs to be well-shaped for an STI. Other structures, such as a BILD and relatively thin bottom spacer, can be used in lieu of the STI in accordance with one or more embodiments to provide final structures having relatively lower contact resistances.

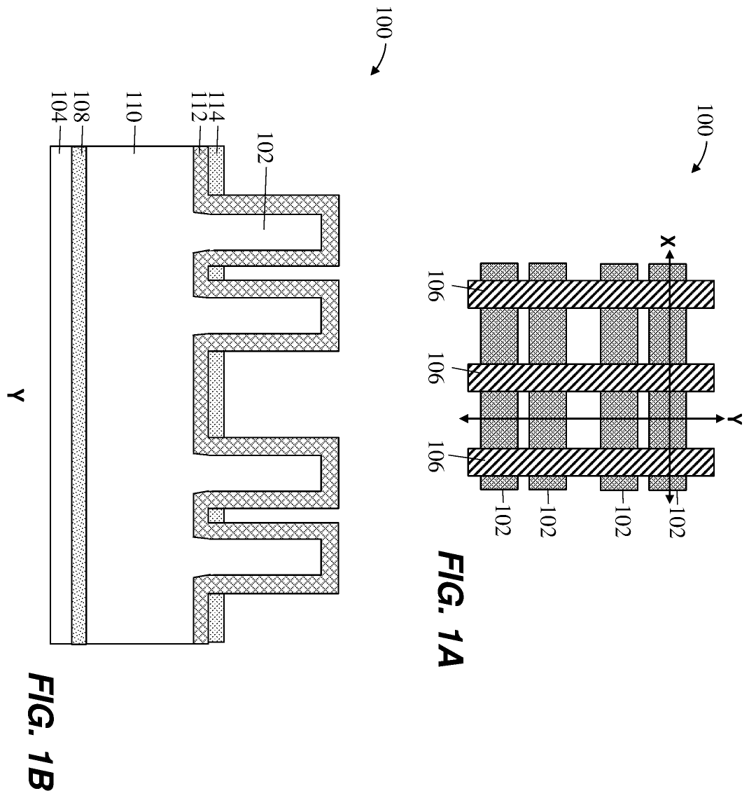

Turning now to a more detailed description of fabrication operations and resulting structures according to aspects of the disclosure, FIG. 1A depicts a top-down reference view of a semiconductor wafer 100 after an initial set of fabrication operations have been applied as part of a method of fabricating a final semiconductor device according to one or more embodiments of the disclosure. FIG. 1B depicts a cross-sectional view taken along the line Y (across channel in source/drain region) in FIG. 1A. As shown in FIG. 1B, various FEOL structures have been built in the semiconductor wafer 100. The specific examples of the FEOL structures are illustrative only and are not meant to be particularly limited. For example, the FEOL structures depict a finFET-style transistor architecture. It should be understood, however, that the finFET-style transistor architecture of the FEOL structures is provided for ease of discussion only and that other transistor architectures (e.g., vertical tunneling transistors, planar transistors, nanosheets, etc.) are included in the contemplated scope of this disclosure. Other FEOL structures can be fabricated depending on the needs of a given application, and all such configurations are within the contemplated scope of this disclosure.

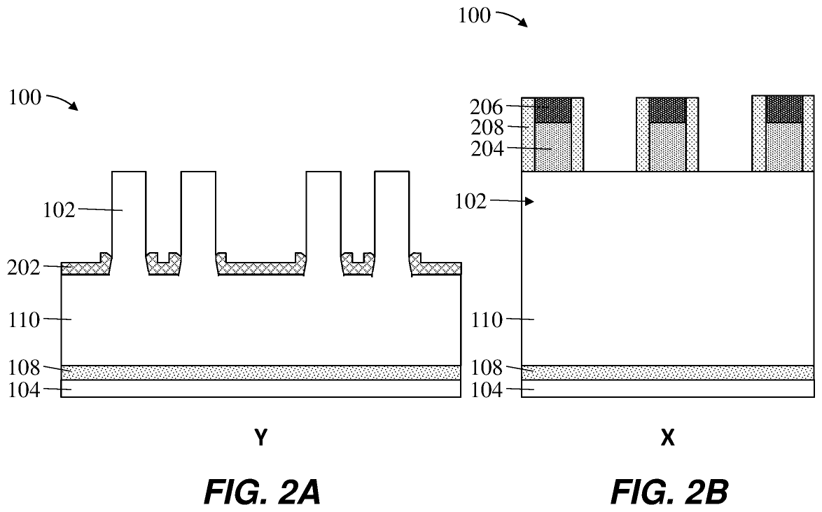

In some embodiments, the semiconductor wafer 100 can include a number of semiconductor fins 102 formed over a substrate 104 and respective sacrificial gate(s) 106 (refer to FIG. 2B) formed over channel regions of the one or more nanosheets 104. In some embodiments, the substrate 104 includes an etch stop layer 108 and an additional semiconductor layer 110 over the etch stop layer 108, although other substrate configurations and materials are within the contemplated scope of this disclosure.

The substrate 104, etch stop layer 108, and/or semiconductor layer 110 can be made of any suitable substrate material. In some embodiments, for example, the substrate 104 and/or semiconductor layer 110 can include monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlInAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys. In some embodiments, the etch stop layer 108 is made form a material selected to have etch selectivity with respect to the substrate 104 and/or semiconductor layer 110. Potential materials include, for example, a dielectric (e.g., SiO₂), or silicon germanium having a different germanium concentration than the substrate 104 and/or semiconductor layer 110. In some embodiments, portions of the semiconductor layer 110 are patterned (recessed) to define the semiconductor fins 102. The semiconductor layer 110 can be patterned using, for example, a wet etch, a dry etch, or a combination of wet and/or dry etches. In some embodiments, the semiconductor layer 110 is patterned using a RIE.

In some embodiments, a dielectric layer 112 is formed over the semiconductor fins 102 and the semiconductor layer 110. In some embodiments, the dielectric layer 112 is conformally deposited over the semiconductor wafer 100. In some embodiments, the dielectric layer 112 has a thickness of about 10 nm to about 60 nm, although other thicknesses are within the contemplated scope of the disclosure. In some embodiments, the dielectric layer 112 is conformally deposited using CVD, PECVD, ultrahigh vacuum CVD (UHVCVD), rapid thermal CVD (RTCVD), metalorganic CVD (MOCVD), low-pressure CVD (LPCVD), limited reaction processing CVD (LRPCVD), ALD, PVD, chemical solution deposition, molecular beam epitaxy (MBE), or other like process in combination with a wet or dry etch process. The dielectric layer 112 can be made of any suitable dielectric material, such as, for example, silicon oxide, silicon nitride, silicon carbide, hydrogenated silicon carbonitrides (SiC(N, H)), silicon oxynitrides (SiC(N, O, H)), and silicon borocarbonitrides (SiBCN), although other dielectrics are within the contemplated scope of this disclosure.

In some embodiments, an organic planarization layer (OPL) 114 can be formed over the dielectric layer 112. The OPL 114 can be formed over a surface of the semiconductor wafer 100 using any suitable process. In some embodiments, the OPL 114 can be applied using, for example, spin coating technology. In some embodiments, the OPL 114 can include a photo-sensitive organic polymer having a light-sensitive material that, when exposed to electromagnetic (EM) radiation, is chemically altered and thus configured to be removed using a developing solvent. For example, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). More generally, for example, the OPL 114 can include any organic polymer and a photo-active compound having a molecular structure that can attach to the molecular structure of the organic polymer.

In some embodiments, the OPL 114 is partially recessed to expose sidewalls and a topmost surface of the dielectric layer 112 (refer to FIG. 1B). The OPL 114 can be recessed using, for example, a wet etch, a dry etch, or a combination of wet and/or dry etches. In some embodiments, the OPL 114 is patterned selective to the dielectric layer 112.

FIG. 2A depicts a cross-sectional view taken along line Y in FIG. 1A. FIG. 2B depicts a cross-sectional view taken along line X (across gate in channel region) in FIG. 1A. As shown in FIG. 2A, the dielectric layer 112 can be patterned to define a bottom spacer 202. In some embodiments, the bottom spacer 202 can be patterned to a thickness of less than 10 nm, or less than 6 nm, for example, 4 nm, although other thicknesses are within the contemplated scope of this disclosure. Notably, the relatively thin (sub-10 nm) thickness of the bottom spacer 202 is readily distinguishable from conventional shallow trench isolation (STI) regions, which are 10s of nanometers thick (or thicker), serving as a physical signature for the process described herein.

In some embodiments, spacer chamfering exposes sidewalls of the semiconductor fins 102, although other patterning techniques, such as a wet etch and/or dry etch, are within the contemplated scope of this disclosure. As further shown in FIG. 2A, the OPL 114 can be removed using, for example, an OPL ash, to expose remaining portions of the bottom spacer 202.

As shown in FIG. 2B, a sacrificial gate 204 (sometimes referred to as a dummy gate) is formed over channel regions of the semiconductor fins 102. As used herein, a “channel region” refers to the portion of a fin over which a gate is formed, and through which current passes from source to drain in the final device (after gate metallization). The sacrificial gate 204 can be made of any suitable material, such as, for example, amorphous silicon or polysilicon. Any known method for patterning a sacrificial gate can be used, such as, for example, a wet etch, a dry etch, or a combination of sequential wet and/or dry etches. In some embodiments, a gate hard mask 206 is formed over the sacrificial gate 204. The gate hard mask 206 can include any suitable hard mask material, such as, for example, silicon nitride.

In some embodiments, dielectric material is deposited over the semiconductor wafer 100 to define gate spacers 208. In some embodiments, the dielectric material is conformally deposited over the semiconductor wafer 100 and then patterned (etched) to define the gate spacers 208. The dielectric material can include, for example, silicon oxide, silicon nitride, silicon carbide, hydrogenated silicon carbonitrides, silicon oxynitrides, and silicon borocarbonitrides, although other dielectrics are within the contemplated scope of the disclosure. Notably, in some embodiments, the respective materials for the bottom spacer 202 and the gate spacers 208 are selected such that the gate spacers 208 can be patterned (via, e.g., a spacer RIE) selective to the bottom spacer 202.

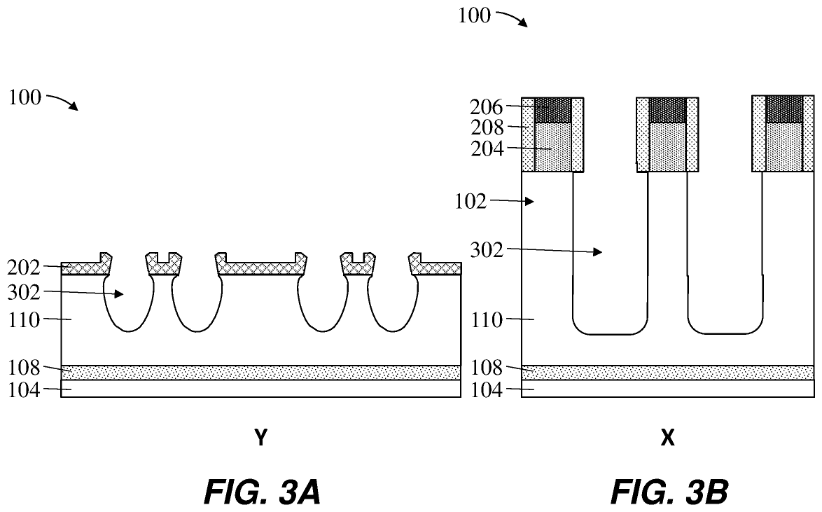

FIG. 3A depicts a cross-sectional view taken along line Y in FIG. 1A. FIG. 3B depicts a cross-sectional view taken along line X (across gate in channel region) in FIG. 1A. As shown in FIGS. 3A and 3B, the semiconductor fins 102 and the semiconductor layer 110 can be recessed to define a placeholder cavity 302. The semiconductor fins 102 and the semiconductor layer 110 can be patterned using, for example, a wet etch, a dry etch, or a combination of wet and/or dry etches. In some embodiments, the semiconductor layer 102 and the semiconductor layer 110 is patterned using a RIE. In some embodiments, the semiconductor layer 102 and the semiconductor layer 110 is patterned using a RIE and lateral etch (as shown). In this manner, a portion of the placeholder cavity 302 will undercut the bottom spacer 202 and/or gate spacers 208. The semiconductor layer 102 and the semiconductor layer 110 can be patterned selective to the bottom spacer 202 and/or gate spacers 208.

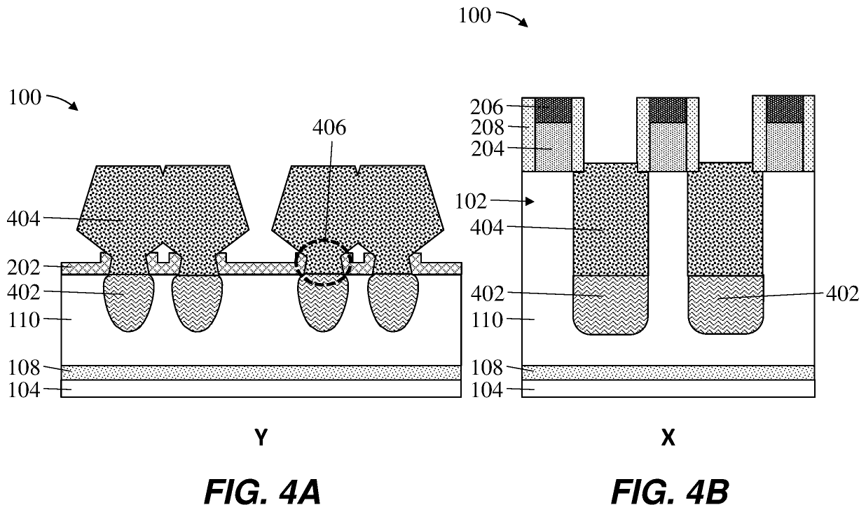

FIG. 4A depicts a cross-sectional view taken along line Y in FIG. 1A. FIG. 4B depicts a cross-sectional view taken along line X (across gate in channel region) in FIG. 1A. As shown in FIGS. 4A and 4B, the placeholder cavity 302 can be filled to define a backside placeholder 402. In some embodiments, the backside placeholder 402 (also referred to as a sacrificial backside placeholder) is formed by filling the placeholder cavity 302 with a sacrificial material such as, for example, silicon germanium. In some embodiments, the silicon germanium (or other sacrificial material) is epitaxially grown from exposed surfaces of the semiconductor layer 110 in the placeholder cavity 302.

In some embodiments, source/drain regions 404 are formed over the backside placeholder 402. As shown in FIG. 4A, the source/drain regions 404 can include a lower portion 406 confined by sidewalls of the bottom spacer 202. Remaining portions of the source/drain regions 404 can be referred to as upper portions (not separately indicated). As further shown in FIG. 4A, adjacent pairs of the source/drain regions 404 can be merged to define a single source/drain region (not separately indicated).

The source/drain regions 404 can be epitaxially grown using, for example, vapor-phase epitaxy (VPE), molecular beam epitaxy (MBE), liquid-phase epitaxy (LPE), or other suitable processes. The source/drain regions 404 can be semiconductor materials epitaxially grown from gaseous or liquid precursors. In some embodiments of the disclosure, the gas source for the epitaxial deposition of semiconductor material includes a silicon containing gas source, a germanium containing gas source, or a combination thereof. For example, a silicon layer can be epitaxially deposited (or grown) from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. A germanium layer can be epitaxially deposited from a germanium gas source that is selected from the group consisting of germane, digermane, halogermane, dichlorogermane, trichlorogermane, tetrachlorogermane and combinations thereof. A silicon germanium alloy layer can be epitaxially formed utilizing a combination of such gas sources. Carrier gases like hydrogen, nitrogen, helium and argon can be used. In some embodiments of the disclosure, the epitaxial semiconductor materials include carbon doped silicon (Si:C). This Si:C layer can be grown in the same chamber used for other epitaxy steps or in a dedicated Si:C epitaxy chamber. The Si:C can include carbon in the range of about 0.2 percent to about 3.0 percent.

Epitaxially grown silicon and silicon germanium can be doped by adding n-type dopants (e.g., P or As) or p-type dopants (e.g., Ga, B, BF₂, or Al) as desired. In some embodiments, the source/drain regions 404 are of opposite doping type. In some embodiments, the source/drain regions 404 are of the same doping type. In some embodiments, the source/drain regions 404 can be epitaxially formed and doped by a variety of methods, such as, for example, in-situ doped epitaxy (doped during deposition), doped following the epitaxy, or by implantation and plasma doping. The dopant concentration in the doped regions can range from 1×10¹⁹ cm⁻³ to 2×10²¹ cm⁻³, or between 1×10²⁰ cm⁻³ and 1×10²¹ cm⁻³.

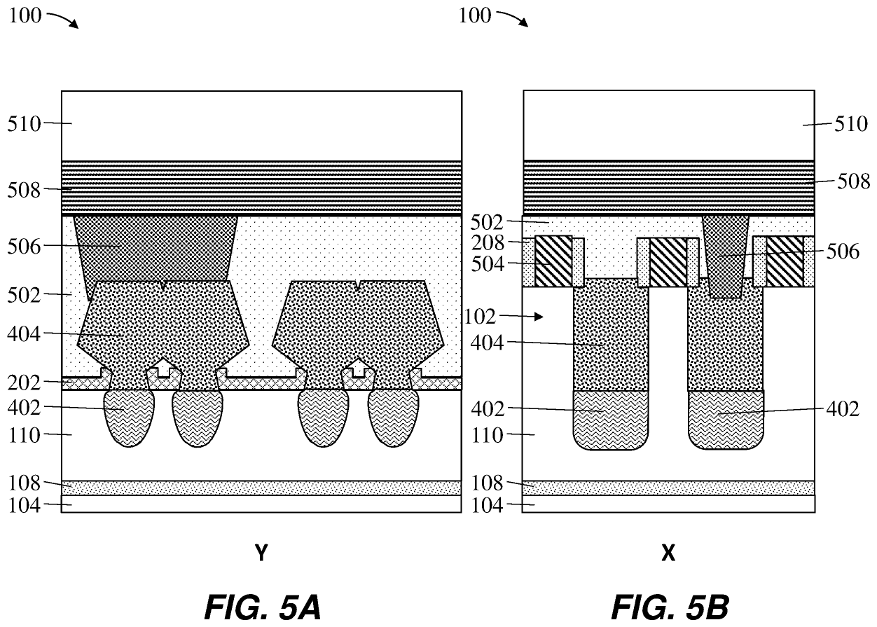

FIG. 5A depicts a cross-sectional view taken along line Y in FIG. 1A. FIG. 5B depicts a cross-sectional view taken along line X (across gate in channel region) in FIG. 1A. As shown in FIGS. 5A and 5B, an interlayer dielectric (ILD) 502 is formed over the source/drain regions 404. The ILD 502 can be made of any suitable dielectric material, such as, for example, oxides, a low-k dielectric, nitrides, silicon nitride, silicon oxide, SiON, SiC, SiOCN, and SiBCN. In some embodiments, the ILD 502 is deposited over the semiconductor wafer 100 and the semiconductor wafer 100 is then planarized using, for example, CMP.

In some embodiments, the gate hard mask 206 and sacrificial gate 204 can be removed and replaced with a conductive gate 504. The conductive gate 504 can be a high-k metal gate (HKMG) formed over channel regions of the semiconductor fins 102 using, for example, known replacement metal gate (RMG) processes, or so-called gate-last processes. In some embodiments, the conductive gate 504 can include a gate dielectric and a work function metal stack (not separately depicted). In some embodiments, the gate dielectric is a high-k dielectric film formed on a surface (sidewall) of the semiconductor fins 102. The high-k dielectric film can be made of, for example, silicon oxide, silicon nitride, silicon oxynitride, boron nitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials can further include dopants such as lanthanum and aluminum. In some embodiments, the high-k dielectric film can have a thickness of about 0.5 nm to about 4 nm.

In some embodiments, one or more frontside source/drain contact(s) 506 are formed over the source/drain regions 404. The frontside source/drain contact(s) 506 can be referred to as merged middle of line (MOL) contacts. The frontside source/drain contact(s) 506 can be formed from conductive materials that include copper or a non-copper metal (e.g., tungsten, titanium, tantalum, ruthenium, zirconium, cobalt, aluminum, platinum), alloys thereof, conducting metallic compound material (e.g., tantalum nitride, titanium nitride, tantalum carbide, titanium carbide, titanium aluminum carbide, tungsten silicide, tungsten nitride, cobalt silicide, nickel silicide, titanium silicide), conductive carbon, or any suitable combination of these materials.

In some embodiments, a frontside interconnect 508 (which itself can include any number of levels of vias and lines) can be formed over the semiconductor wafer 100. The frontside interconnect 508 shown is merely illustrative and the semiconductor wafer 100 can include any number of BEOL structures (e.g., additional interconnect layers, vias, lines, etc.) and all such configurations are within the contemplated scope of this disclosure.

In some embodiments, a carrier wafer 510 (also referred to as a bonding carrier wafer) is formed over the frontside interconnect 508. The carrier wafer 510 can be made of a same or different material as the substrate 104, such as silicon and/or a wafer handling material.

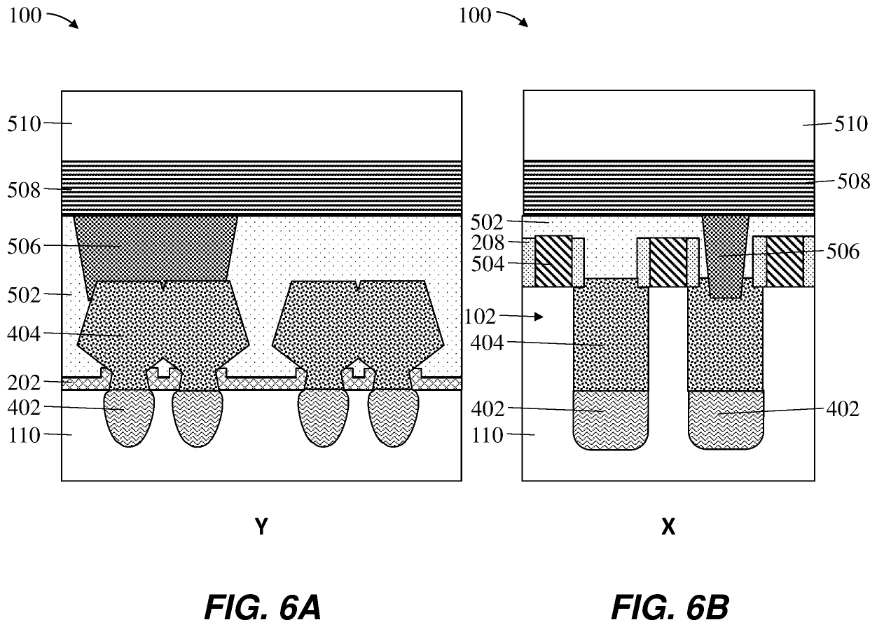

FIG. 6A depicts a cross-sectional view taken along line Y in FIG. 1A. FIG. 6B depicts a cross-sectional view taken along line X (across gate in channel region) in FIG. 1A. As shown in FIGS. 6A and 6B, in some embodiments, the semiconductor wafer 100 is flipped and the substrate 104 is removed post-wafer flip. In some embodiments, removal of the substrate 104 lands (or stops) on the etch stop layer 108. For example, the substrate 104 can be removed by grinding and/or chemical-mechanical planarization (CMP), followed by dry etch and wet etch processes to remove substrate 104 (e.g., silicon), stopping on the etch stop layer 108. Note that the orientation of the semiconductor wafer 100 shown in FIGS. 6A and 6B remains fixed for ease of discussion. In some embodiments, the etch stop layer 108 is removed after stripping off the substrate 104 to expose portions of the semiconductor layer 110.

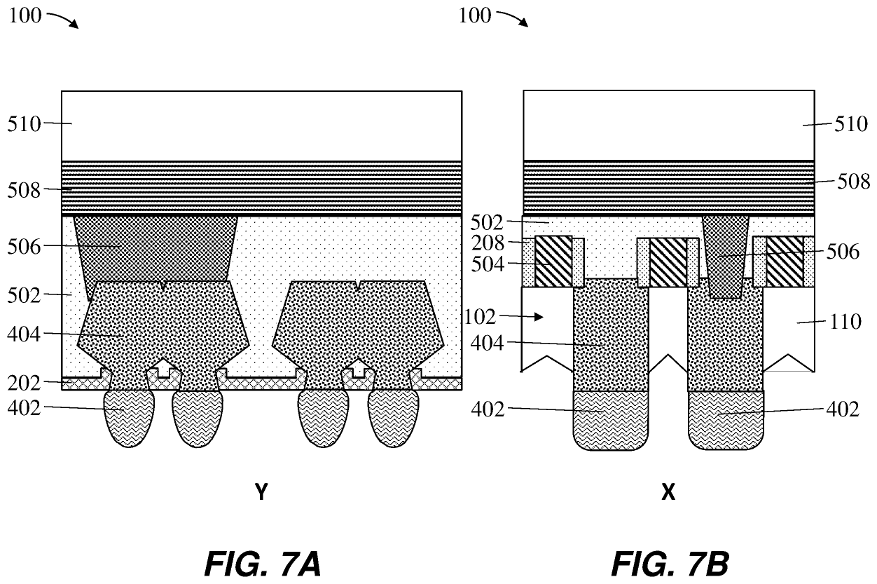

FIG. 7A depicts a cross-sectional view taken along line Y in FIG. 1A. FIG. 7B depicts a cross-sectional view taken along line X (across gate in channel region) in FIG. 1A. As shown in FIGS. 7A and 7B, in some embodiments, the semiconductor layer 110 is recessed after removing the etch stop layer 108. In some embodiments, the semiconductor layer 110 is recessed selective to the backside placeholder 402 and/or the bottom spacer 202. In some embodiments, the semiconductor layer 110 is recessed to expose sidewalls of the source/drain regions 404 (refer to FIG. 7B). The semiconductor layer 110 can be recessed using, for example, a wet etch, a dry etch, or a combination of wet and/or dry etches.

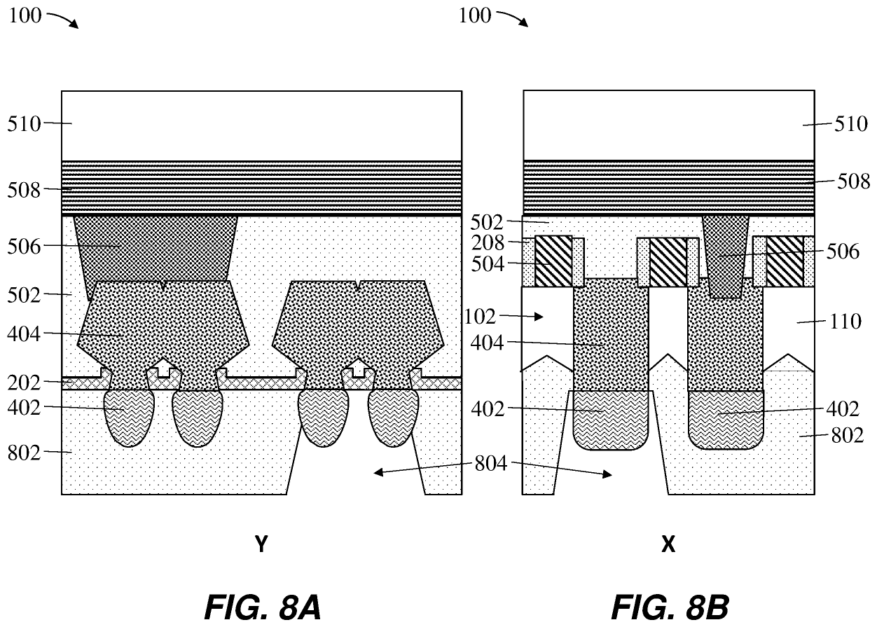

FIG. 8A depicts a cross-sectional view taken along line Y in FIG. 1A. FIG. 8B depicts a cross-sectional view taken along line X (across gate in channel region) in FIG. 1A. As shown in FIGS. 8A and 8B, in some embodiments, a backside interlayer dielectric (BILD) 802 is formed over the semiconductor wafer 100. The BILD 802 can be made from any suitable dielectric material, such as, for example, a low-k dielectric, a nitride, silicon nitride, silicon oxide, SiON, SiC, SiOCN, SiBCN, etc. In some embodiments, the BILD 802 is made of a material selected to allow for etch selectivity with respect to the backside placeholder 402. In some embodiments, the BILD 802 is deposited over the bottom spacer 202 (refer FIG. 8A) and the recessed surface of the semiconductor layer 110 (refer FIG. 8B) and the semiconductor wafer 100 is then planarized using, for example, CMP.

In some embodiments, the BILD 802 can be patterned to define a backside cavity 804. This process can be referred to as a backside contact patterning. The BILD 802 can be patterned using, for example, a wet etch, a dry etch, or a combination of wet and/or dry etches. In some embodiments, the BILD 802 is patterned using a RIE to expose the backside placeholder 402. In some embodiments, the BILD 802 is patterned using a RIE selective to the bottom spacer 202 and/or backside placeholder 402.

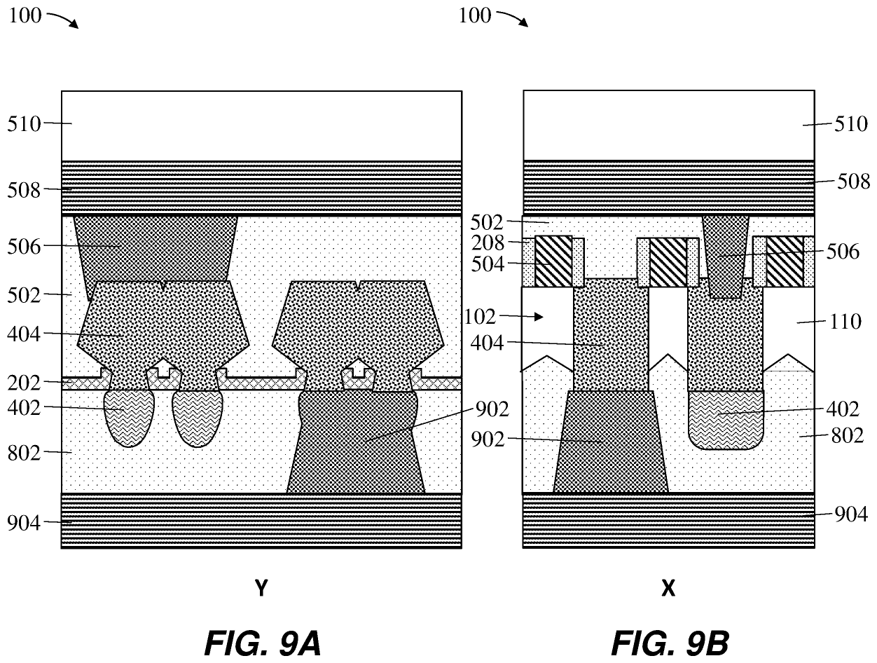

FIG. 9A depicts a cross-sectional view taken along line Y in FIG. 1A. FIG. 9B depicts a cross-sectional view taken along line X (across gate in channel region) in FIG. 1A. As shown in FIGS. 9A and 9B, in some embodiments, the backside placeholder 402 in the backside cavity 804 can be removed using for example, a wet etch, a dry etch, or a combination of wet and/or dry etches. In some embodiments, the backside placeholder 402 in the backside cavity 804 can be removed to expose a surface of the source/drain regions 404.

In some embodiments, the backside placeholder 402 is removed and the backside cavity 804 is filled with conductive material (e.g., metals, doped semiconductors, etc.) to define a backside contact 902 (also referred to as a backside S/D contact and/or as a merged backside contact). This process can be referred to as a backside S/D contact metallization.

In some embodiments, a backside interconnect 904 is formed over the semiconductor wafer 100. The backside interconnect 904 can include, for example, a backside power delivery network (BSPDN), although other interconnect structures are within the contemplated scope of this disclosure. The backside interconnect 904 can include any number of conductive/metal layers, lines, and vias, and can be formed in a similar manner as the frontside interconnect 508 discussed previously, except that the backside interconnect 904 is formed on an opposite side of the semiconductor wafer 100. Additional backside layers, structures, and dielectrics (omitted for clarity) can be formed before or after the backside interconnect 904.

After backside processing is complete, the semiconductor wafer 100 can be finalized using known processes (e.g., additional BEOL, far back end of line (FBEOL), and packaging processes used to define a final device, including the incorporation of additional frontside and/or backside metallization layers).

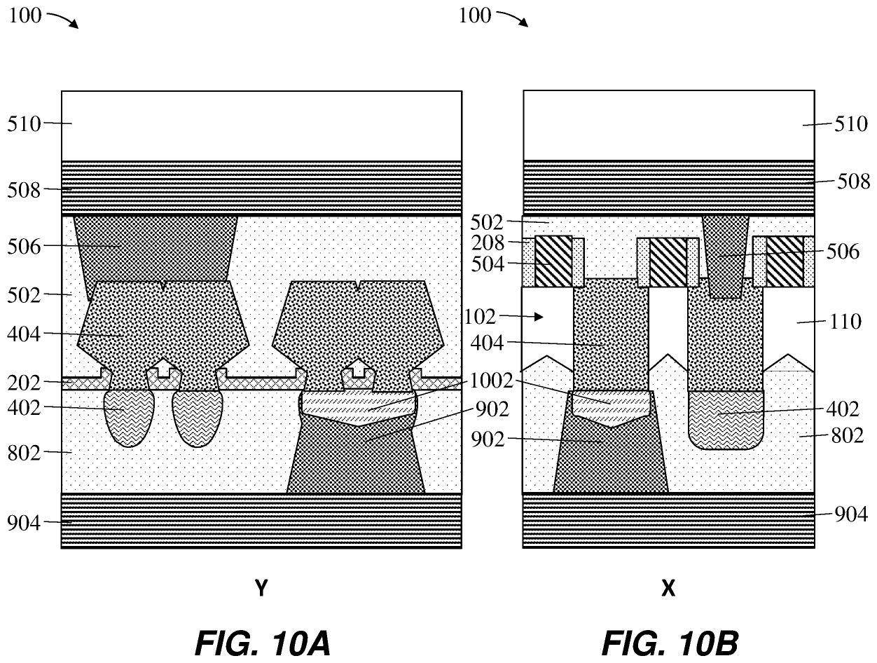

FIG. 10A depicts a cross-sectional view taken along line Y in FIG. 1A. FIG. 10B depicts a cross-sectional view taken along line X (across gate in channel region) in FIG. 1A. In some embodiments, prior to forming the backside contact 902, a backside trench epitaxy 1002 is formed in the backside cavity 804 after removing the backside placeholder 402 to expose the source/drain regions 404 (refer to FIGS. 8A and 8B). In this manner, the contact area to the source/drain regions 404 can be increased to further improve (lower) contact resistance to the later-formed backside contact 902.

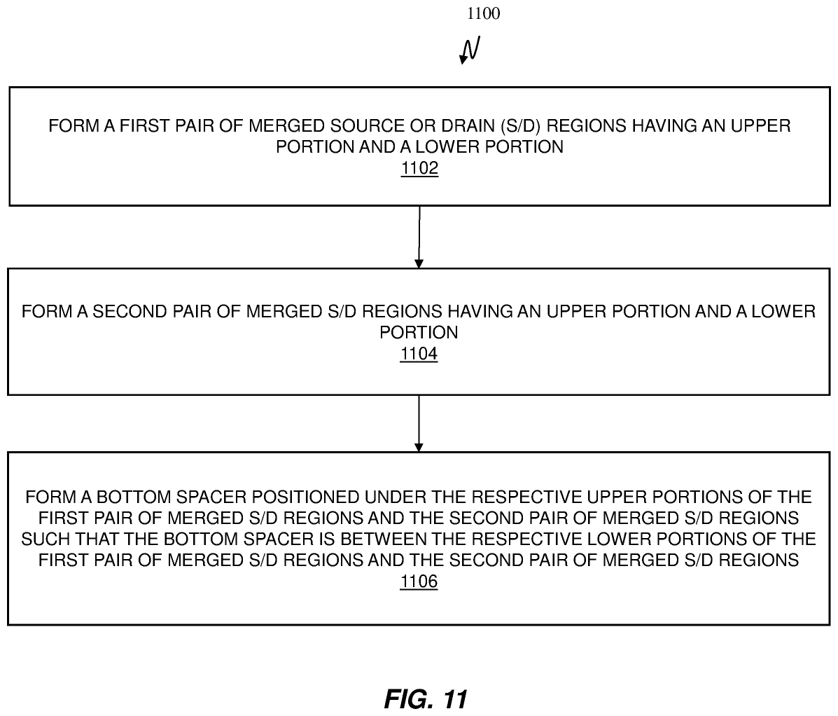

FIG. 11 depicts a flow diagram illustrating a method 1100 for providing for a backside merged source/drain contacts according to one or more embodiments. The method 1100 is described in reference to FIGS. 1A-10B and may include additional blocks not depicted in FIG. 11. Although depicted in a particular order, the blocks depicted in FIG. 11 can be rearranged, subdivided, and/or combined.

As shown at block 1102, the method includes forming a first pair of merged S/D regions. The first pair of merged S/D regions include an upper portion and a lower portion. In some embodiments, the first pair of merged S/D regions are electrically coupled to a frontside interconnect through a merged middle of line (MOL) contact.

As shown at block 1104, the method includes forming a second pair of merged S/D regions. The second pair of merged S/D regions include an upper portion and a lower portion. In some embodiments, the second pair of merged S/D regions are electrically coupled to a backside interconnect through a merged backside contact.

As shown at block 1106, the method includes forming a bottom spacer positioned under the respective upper portions of the first pair of merged S/D regions and the second pair of merged S/D regions. The bottom spacer is positioned between the respective lower portions of the first pair of merged S/D regions and the second pair of merged S/D regions.

In some embodiments, the semiconductor device does not include a shallow trench isolation region.

In some embodiments, the method includes forming backside placeholders in direct contact with lower portions of the first pair of merged S/D regions.

In some embodiments, a topmost surface of the merged backside contact is in direct contact with a bottommost surface of the bottom spacer. In some embodiments, the topmost surface of the merged backside contact is in direct contact with the respective lower portions of the second pair of merged S/D regions.

In some embodiments, the respective lower portions of the first pair of merged S/D regions and the second pair of merged S/D regions are confined between sidewalls of the bottom spacer.

In some embodiments, the method includes forming a pair of semiconductor fins. In some embodiments, a bottommost surface of the pair of semiconductor fins is indented towards a frontside of the semiconductor device (refer to FIG. 7B).

In some embodiments, the method includes forming a trench epitaxy directly between the merged backside contact and the respective lower portions of the second pair of merged S/D regions.

In some embodiments, the bottom spacer includes a thickness of less than 6 nanometers.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc.

The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the disclosure, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
forming a first pair of merged source or drain (S/D) regions, the first pair of merged S/D regions comprising an upper portion and a lower portion;
forming a second pair of merged S/D regions, the second pair of merged S/D regions comprising an upper portion and a lower portion; and
forming a bottom spacer positioned under the respective upper portions of the first pair of merged S/D regions and the second pair of merged S/D regions, the bottom spacer between the respective lower portions of the first pair of merged S/D regions and the second pair of merged S/D regions;
wherein the first pair of merged S/D regions are electrically coupled to a frontside interconnect through a merged middle of line (MOL) contact; and
wherein the second pair of merged S/D regions are electrically coupled to a backside interconnect through a merged backside contact.

2. The method of claim 1, wherein the semiconductor device does not include a shallow trench isolation (STI).

3. The method of claim 1, further comprising forming backside placeholders in direct contact with lower portions of the first pair of merged S/D regions.

4. The method of claim 1, wherein a topmost surface of the merged backside contact is in direct contact with a bottommost surface of the bottom spacer.

5. The method of claim 4, wherein the topmost surface of the merged backside contact is in direct contact with the respective lower portions of the second pair of merged S/D regions.

6. The method of claim 1, wherein the respective lower portions of the first pair of merged S/D regions and the second pair of merged S/D regions are confined between sidewalls of the bottom spacer.

7. The method of claim 1, further comprising forming a pair of semiconductor fins.

8. The method of claim 7, wherein a bottommost surface of the pair of semiconductor fins is indented towards a frontside of the semiconductor device.

9. The method of claim 1, further comprising forming a trench epitaxy directly between the merged backside contact and the respective lower portions of the second pair of merged S/D regions.

10. The method of claim 1, wherein the bottom spacer comprises a thickness of less than 6 nanometers.

11. A semiconductor device comprising:
a first pair of merged source or drain (S/D) regions, the first pair of merged S/D regions comprising an upper portion and a lower portion;
a second pair of merged S/D regions, the second pair of merged S/D regions comprising an upper portion and a lower portion; and
a bottom spacer positioned under the respective upper portions of the first pair of merged S/D regions and the second pair of merged S/D regions, the bottom spacer between the respective lower portions of the first pair of merged S/D regions and the second pair of merged S/D regions;
wherein the first pair of merged S/D regions are electrically coupled to a frontside interconnect through a merged middle of line (MOL) contact; and
wherein the second pair of merged S/D regions are electrically coupled to a backside interconnect through a merged backside contact.

12. The semiconductor device of claim 11, wherein the semiconductor device does not include a shallow trench isolation (STI).

13. The semiconductor device of claim 11, further comprising backside placeholders in direct contact with lower portions of the first pair of merged S/D regions.

14. The semiconductor device of claim 11, wherein a topmost surface of the merged backside contact is in direct contact with a bottommost surface of the bottom spacer.

15. The semiconductor device of claim 14, wherein the topmost surface of the merged backside contact is in direct contact with the respective lower portions of the second pair of merged S/D regions.

16. The semiconductor device of claim 11, wherein the respective lower portions of the first pair of merged S/D regions and the second pair of merged S/D regions are confined between sidewalls of the bottom spacer.

17. The semiconductor device of claim 11, further comprising a pair of semiconductor fins.

18. The semiconductor device of claim 17, wherein a bottommost surface of the pair of semiconductor fins is indented towards a frontside of the semiconductor device.

19. The semiconductor device of claim 11, further comprising a trench epitaxy directly between the merged backside contact and the respective lower portions of the second pair of merged S/D regions.

20. The semiconductor device of claim 11, wherein the bottom spacer comprises a thickness of less than 6 nanometers.
